(19) United States
(12) Patent Application Publication
(10) Pub. No.: US 2004/0135242 A1
(43) Pub. Date: Jul. 15, 2004

(54) Stacked structure of chips

(76) Inventor: Chung Hsien Hsin, Hsinchu Hsien (TW)

Correspondence Address: Keith Kline, PRO-TECHTOR INTERNATIONAL SERVICES, 20775 Norada Court, Saratoga, CA, 95070-3018, US

(21) Appl. No.: 10/340,309

(22) Filed: Jan. 9, 2003

(51) Int. Cl. H01L 23/02

(52) U.S. Cl. 257/686

(57) ABSTRACT

A stacked structure includes a substrate, a lower chip, wires, an adhesive layer, an upper chip and a glue layer. A cavity and signal input terminals are formed on the substrate. The lower chip is placed within the cavity and adhered to the substrate. Each wire has a first terminal and a second terminal. The first terminals are electrically connected to bonding pads of the lower chip. The second terminals are electrically connected to the signal input terminals. The adhesive layer is coated on the lower chip. The upper chip has a lower surface and an upper surface formed with bonding pads. The upper chip is adhered to the lower chip by the adhesive layer. The wires electrically connect the bonding pads to the signal input terminals of the substrate. The glue layer is applied to the substrate to encapsulate the upper chip, lower chip and wires.

### BACKGROUND OF THE INVENTION

1. Field of the Invention

The invention relates to a stacked structure of chips, and more particularly to a stacked structure, in which chips or integrated circuits may be effectively stacked to facilitate the manufacturing processes.

2. Description of the Related Art

In the current technological field, every product needs to be light, thin, and small. Therefore, it is preferable that the integrated circuit has a small volume in order to meet the demands of the products. In the prior art, even if the volumes of integrated circuits are small, they only can be electrically connected to the circuit board in parallel. Because the area of the circuit board is limited, it is not possible to increase the number of the integrated circuits mounted on the circuit board. Therefore, it is difficult to make the products small, thin, and light.

To meet the demands of manufacturing small, thin, and light products, a lot of integrated circuits can be stacked. However, when a lot of integrated circuits are stacked, the upper integrated circuit will contact and press the wires of the lower chip. In this case, the signal transmission to or from the lower chip is easily influenced.

Referring to FIG. 1, a conventional chip stacked structure includes a substrate 10, a lower chip 12, an upper chip 14, a plurality of wires 16 and an isolation layer 18. The lower chip 12 is placed on the substrate 10, the upper chip 14 is stacked above the lower chip 12 with the isolation layer 18 interposed therebetween to form a predetermined gap 20 between a periphery of the lower chip 12 and that of the upper chip 14. Accordingly, a plurality of wires may be electrically connected to the periphery of the lower chip 12 so that the wires 16 are free from being pressed and damaged by the upper chip 14 stacked above the lower chip 12.

However, when this stacked structure is manufactured, an isolation layer 18 has to be formed in advance. Then, the isolation layer 18 has to be adhered to the lower chip 12. Next, the upper chip 14 has to be adhered to the isolation layer 18. Thus, the processes for manufacturing the stacked structure are complicated, and the manufacturing costs are high. In addition, since the wires 16 have to be bonded from the substrate 10 to the lower chip 12 and the upper chip 14, the radians of the curved wires are greater. In this case, the wires 16 may tend to be broken and cannot be easily manufactured with a high yield. Furthermore, when the lower chip 12 is adhered to the substrate 10, overflowed glue may cover the bonding pads and adversely influence the electric connection effects of the wires 16.

### SUMMARY OF THE INVENTION

An object of the invention is to provide a stacked structure, in which chips may be effectively stacked so that the manufacturing speed may be increased.

Another object of the invention is to provide a stacked structure of chips capable of avoiding overflowed glue, which may adversely influence the electric connection effects.

Still another object of the invention is to provide a stacked structure of chips capable of avoiding broken wires and increasing production yields and costs.

To achieve the above-mentioned objects, the invention provides a stacked structure comprising a substrate, a lower chip, a plurality of wires, an adhesive layer, an upper chip, and a glue layer. The substrate has a first surface and a second surface formed with signal output terminals. A cavity is formed at a central portion of the first surface and a plurality of signal input terminals is formed at a periphery of the first surface. The lower chip has a lower surface and an upper surface formed with a plurality of bonding pads. The lower chip is placed within the cavity with the lower surface of the lower chip adhered to the first surface of the substrate. Each of the wires has a first terminal and a second terminal. The first terminals are electrically connected to the bonding pads of the lower chip, respectively. The second terminals are electrically connected to the signal input terminals on the first surface of the substrate, respectively. The adhesive layer is coated on the upper surface of the lower chip. The upper chip has a lower surface and an upper surface formed with a plurality of bonding pads. The lower surface of the upper chip is adhered to the upper surface of the lower chip by the adhesive layer. The plurality of wires electrically connects the plurality of bonding pads to the signal input terminals of the substrate, respectively. The glue layer is applied to the first surface of the substrate to encapsulate the upper chip, lower chip and wires.

### BRIEF DESCRIPTION OF THE DRAWINGS

FIG. 1 is a cross-sectional view showing a conventional stacked structure of chips.

FIG. 2 is a cross-sectional view showing a stacked structure of chips of the invention.

FIG. 3 is a first schematic illustration showing a step of manufacturing the stacked structure of the invention.

FIG. 4 is a second schematic illustration showing another step of manufacturing the stacked structure of the invention.

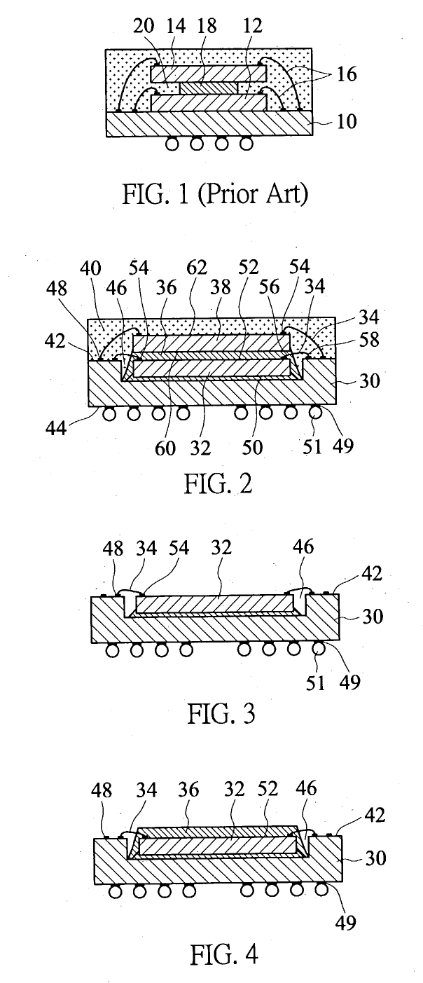

### DETAILED DESCRIPTION OF THE INVENTION

Referring to FIG. 2, a stacked structure of the invention includes a substrate 30, a lower chip 32, a plurality of wires 34, an adhesive layer 36, an upper chip 38 and a glue layer 40.

The substrate 30 has a first surface 42 and a second surface 44. A cavity 46 is formed at a central portion of the first surface 42, and a plurality of signal input terminals 48 is formed at a periphery of the first surface 42. The second surface 44 is formed with signal output terminals 49 for electrically connected to a circuit board (not shown). BGA metallic balls 51 are formed on the signal output terminals 49, respectively.

The lower chip 32 has a lower surface 50 and an upper surface 52 formed with a plurality of bonding pads 54. The lower chip 32 is placed within the cavity 46 with the lower surface 50 adhered to the first surface 42 of the substrate 30.

Each of the wires 34 has a first terminal 56 and a second terminal 58. The, the first terminals 56 are electrically connected to the bonding pads 54 of the lower chip 32. The second terminals 58 are electrically connected to the signal input terminals 48 on the first surface 42 of the substrate 30 so that signals from the lower chip 32 may be transferred to the substrate 30.

The adhesive layer 36 is applied to the upper surface 52 of the lower chip 32 so that a plurality of wires 34 may be encapsulated.

The upper chip 38 has a lower surface 60 and an upper surface 62 formed with a plurality of bonding pads 54. The lower surface 60 of the upper chip 38 is adhered to the upper surface 52 of the lower chip 32 by the adhesive layer 36. The wires 34 are electrically connected from the bonding pads 54 to the signal input terminals 48 of the substrate 30.

The glue layer 40 is applied to the first surface 42 of the substrate 30 to encapsulate the upper chip 38, lower chip 32 and the wires 34.

Referring to FIG. 3, the stacked structure of the invention is manufactured by providing a substrate 30 in advance. Then, a cavity 46 is formed at a central portion of a first surface 42 of the substrate 30, and a plurality of signal input terminals 48 is formed at a periphery of the substrate 30. Next, a plurality of signal output terminals 49 is formed on a second surface 44 of the substrate 30, wherein the signal output terminals 49 are formed with BGA (ball grid array) metallic balls 51. Then, a lower chip 32 is placed within the cavity 46 of the substrate 30 and adhered to the substrate 30, and a plurality of wires 34 is provided to electrically connect the bonding pads 54 of the lower chip 32 to the signal input terminals 48 on the first surface 42 of the substrate 30, respectively.

Then, please refer to FIG. 4. An adhesive layer 36 is coated on the upper surface 52 of the lower chip 32 to encapsulate the lower chip 32 and the wires 34. Therefore, the wires 34 are free from being pressed and damaged by the upper chip 38 stacked above the lower chip 32, and the overflowed glue from the adhesive layer 36 may flow to the cavity 46 without contaminating the signal input terminals 48 and influencing the signal transmission effects.

The stacked structure of the invention has the following advantages.

1. The overflowed glue or adhesive from the upper chip 38 and the lower chip 32 may flow to the cavity 46 without contaminating the signal input terminals 48.

2. The upper chip 38 is stacked above the lower chip 32 with the adhesive layer 36 interposed therebetween. In addition, the adhesive layer 36 may protect the wires 34, which may not be pressed and damaged by the upper chip 38.

3. Since the lower chip 32 and the upper chip 38 are located within the cavity 46, the radians of the bonded wires 34 are small. Thus, the wires 34 are free from being broken.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A stacked structure, comprising:
a substrate having a first surface and a second surface formed with signal output terminals, a cavity being formed at a central portion of the first surface and a plurality of signal input terminals being formed at a periphery of the first surface;
a lower chip having a lower surface and an upper surface formed with a plurality of bonding pads, the lower chip being placed within the cavity with the lower surface of the lower chip adhered to the first surface of the substrate;
a plurality of wires, each of which having a first terminal and a second terminal, the first terminals being electrically connected to the bonding pads of the lower chip, respectively, and the second terminals being electrically connected to the signal input terminals on the first surface of the substrate, respectively;
an adhesive layer coated on the upper surface of the lower chip;
an upper chip having a lower surface and an upper surface formed with a plurality of bonding pads, the lower surface of the upper chip being adhered to the upper surface of the lower chip by the adhesive layer, and the plurality of wires electrically connecting the plurality of bonding pads to the signal input terminals of the substrate, respectively; and
a glue layer applied to the first surface of the substrate to encapsulate the upper chip, lower chip and wires.

2. The stacked structure according to claim 1, wherein the signal output terminals on the substrate are formed with BGA (ball grid array) metallic balls.
